(19) United States
(12) Patent Application Publication
(10) Pub. No.: US 2015/0311426 A1
(43) Pub. Date: Oct. 29, 2015

(54) METHOD OF MANUFACTURING A TRANSDUCER

(71) Applicant: National Taiwan University, Taipei City (TW)

(72) Inventors: Hong-Jie TSENG, Taipei City (TW); Wei-Cheng TIAN, Taipei City (TW); Wen-Jong WU, Taipei City (TW)

(73) Assignee: National Taiwan University, Taipei City (TW)

(21) Appl. No.: 14/260,431

(22) Filed: Apr. 24, 2014

(51) Int. Cl. H01L 41/273; H04R 31/00; H01L 41/331; H01L 41/29; H01L 41/316; H01L 41/317

(52) U.S. Cl. CPC H01L 41/273; H01L 41/316; H01L 41/317; H01L 41/331; H01L 41/29; H04R 31/00

(57) ABSTRACT

A method of manufacturing a tactile transducer includes providing a substrate; performing a surface treatment on the substrate by using an electrolysis system; depositing a buffer layer on the substrate; forming a layer of a piezoactive thin film on the substrate; baking the piezoactive thin film; annealing the piezoactive thin film; performing a poling process on the piezoactive thin film; and depositing a top electrode on the piezoactive thin film.

### CROSS-REFERENCE TO RELATED APPLICATIONS

This invention is partly disclosed in articles by Wei-Cheng Tian et al. entitled “Flexible PZT Thin Film Tactile Sensor for Biomedical Monitoring”, published on Apr. 25, 2013, and “P(VDF-TrFE) Poly-Based Thin Films Deposited on Stainless Steel Substrates Treated Using Water Dissociation for Flexible Tactile Sensor Development”, published on Oct. 30, 2013, Sensors 2013, ISSN 1424-8220.

### FIELD OF THE INVENTION

The present invention relates to a method of manufacturing a transducer, in particular to a method of manufacturing a transducer with strong adhesion strength between a piezoactive thin film and a substrate.

### BACKGROUND OF THE INVENTION

Recently, with the development of tele-homecare systems, wearable electronics with a transducer for momentarily monitoring patients' vital signs, such as blood pressure, heart rate, pulse waveform in artery regions etc. have been developing rapidly and improving. Human body pulse waveforms can be monitored for diseases, such as cardiovascular disease and arteriosclerosis. To satisfy different inspection needs, transducers should be adaptable to measure human pulses from several areas with different curve radii, e.g. carotid, brachial, finger, ankle, radial, artery, or the apical region. In addition, the transducers used as part of microelectromechanical systems (MEMS) devices have several merits: small size, mature technologies, and low cost processing.

Nowadays, there are various types of transducers in the market, such as capacitive-based, piezoresistive-based, and piezoelectric-based. The capacitive-based transducers typically include a flexible membrane and gap, and they can be employed in mobile robot contact force arrays, pressure transducers, and tactile sensing arrays. The piezoresistive-based transducers exhibit features whose resistances change when pressure is applied, so that the piezoresistive-based transducers can be used for force transducers, pressure transducers, and tactile transducers. The piezoelectric-based transducers are commonly used for converting mechanical energy into electrical energy, so they are used widely in biomedical transducers.

The traditional method of manufacturing the transducers is forming a layer of piezoactive (e.g. piezoelectric or piezoresistive) material on a silicon or plastic substrate by sputter, MOCVD, CVD, ALD, or sol-gel process. However, the adhesion strength between the piezoactive thin film and the substrate is weak. In the conventional adhesion test, after using the 3M Scotch tape to detach the piezoactive thin film, less than 45% of the piezoactive thin film area is resided on the substrate.

Furthermore, in order to improve the adhesion strength between the piezoactive thin film and the substrate, a surface treatment process is applied. Conventionally, the surface treatment process is implemented by a plasma, laser, or heat method. However, these methods have high costs or high operation temperatures, and the treatment area is restricted.

It is therefore necessary to provide a new technological solution to solve the above technical problems.

### SUMMARY OF THE INVENTION

A primary object of the present invention is to provide a method of manufacturing a transducer that can produce the transducer with strong adhesion strength between the piezoactive thin film and the substrate. Furthermore, the transducer is able to adapt to several portions with different curve radii.

To achieve the above object, the present invention provides a method of manufacturing a transducer. The method comprises the following steps: providing a substrate; performing a surface treatment on the substrate by using an electrolysis system; depositing a buffer layer on the substrate; forming a layer of a piezoactive thin film on the substrate; baking the piezoactive thin film; annealing the piezoactive thin film; performing a poling process on the piezoactive thin film; and depositing a top electrode on the piezoactive thin film.

According to an aspect of the present invention, the step of performing the surface treatment on the substrate comprises deploying the substrate on an anode side of the electrolysis system, and applying a value of positive voltage in a range of between 0 to 100 volts to the electrolysis system.

According to another aspect of the present invention, the step of performing the surface treatment on the substrate comprises deploying the substrate on a cathode side of the electrolysis system, and applying a value of negative voltage in a range of between −100 to 0 volts to the electrolysis system,

According to another aspect of the present invention, further comprises preparing a precursor solution before forming the layer of the piezoactive thin film on the substrate, and the layer of the piezoactive thin film is formed on the substrate by applying the precursor solution on the substrate.

According to another aspect of the present invention, the precursor solution comprises at least zirconium ions, titanium ions, and lead ions. The step of preparing the precursor solution comprises the following steps: mixing zirconium n-prop-oxide and titanium iso-prop-oxide for forming a first solution; mixing lead acetate trihydrate and acetate acid for forming a second solution; mixing the first solution with the second solution for forming a mixture solution; and sequentially mixing deionized water, lactic acid, glycerol, and ethylene glycol into the mixture solution.

According to another aspect of the present invention, the step of forming the layer of the piezoactive thin film on the substrate by spin-coating the precursor solution on the substrate comprises: forming at last one layer of photoresist on the substrate; baking the photoresist layer; exposing the photoresist layer to ultraviolet light; patterning the photoresist layer; forming the layer of the piezoactive thin film by applying the precursor solution on the substrate and the photoresist layer; pre-baking the piezoactive thin film; and removing the photoresist layer. The temperature of pre-baking the piezoactive thin film is in a ranged from 120° C. to 150° C.

### BRIEF DESCRIPTION OF THE DRAWINGS

FIG. 1 shows a flow chart of a manufacturing method for a transducer in the first embodiment.

FIG. 2 shows a flow chart for forming the piezoactive thin film layer on the substrate.

FIG. 3 shows a flow chart for preparing a precursor solution.

### DETAILED DESCRIPTION OF THE INVENTION

The structure and the technical means adopted by the present invention to achieve the above and other objects can be best understood by referring to the following detailed description of the preferred embodiments and the accompanying drawings. Furthermore, directional terms described by the present invention, such as upper, lower, front, back, left, right, inner, outer, side, longitudinal/vertical, transverse/horizontal, etc., are only directions by referring to the accompanying drawings, and thus the used directional terms are used to describe and understand the present invention, but the present invention is not limited thereto.

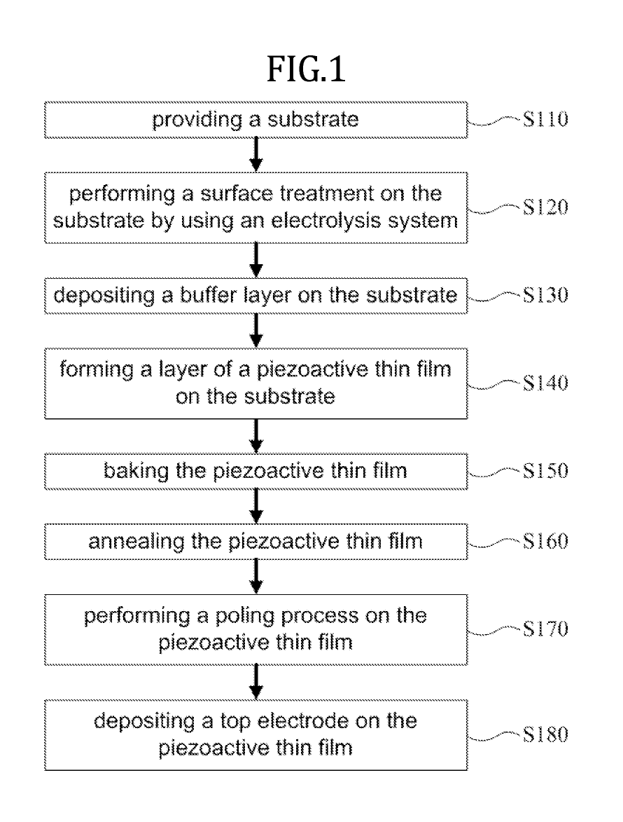

Please refer to FIG. 1. FIG. 1 shows a flow chart of a manufacturing method for a transducer in the first embodiment.

The manufacturing method for the transducer in first embodiment comprises the following steps:

Firstly, in step S110, a substrate is provided. The material of the substrate comprises metal, silicon, stainless steel, polymer, glass, indium-tin-oxide coated polyimide, or platinum-coated silicon. The substrate has a thickness ranging from about 1 micrometer to 20 minimeters, and the preferred thickness of the present invention is in a range of between 1 to 100 micrometers. In some embodiments, the flexibility and the electrical properties (such as J-E curve) of the transducers are dominated by the properties of the substrate material, so that a material with excellent flexibility and electrical properties may be chosen to form the substrate. For example, the flexibility stainless steel substrate is preferred because of its high Poisson's ratio property. Furthermore, for human pulse measurements, the transducer must be suitably implemented on various surface topologies of human body. Thus, the flexible stainless steel substrate is selected, because it has a high robustness property compared with other flexible materials (such as aluminum (Al) foil or polyimide). Moreover, to compare a stainless-steel-based transducer and a silicon-based transducer under the same conditions (same thin film thickness and material), the sensitivity of the stainless-steel-based transducer is 5 times higher than that of the silicon-based transducer.

After the substrate is provided, in step S120, a surface treatment is performed on the substrate by using an electrolysis system for improving an adhesion between the substrate and a piezoactive thin film. A solution in the electrolysis system comprising deionized water, hydrohalic acid solution, oxyacid solution, organic acid solution, hydrofluoric acid solution, alkaline metal aqueous solution, alkaline earth metal aqueous solution, or nitrogen compound aqueous solution. The preferred pH of the solution in the electrolysis system is in a range of 2.5 and 10.0. The electrolysis system comprises a DC power supply, a container, and electrolytes. In the present invention, by using the electrolysis system, the treated area can be large and only restricted by the volume of the substrate container.

As explained in greater detail below, the surface treatment step S120 may be implemented as follows. The substrate is deployed on the anode side of the electrolysis system, and then a positive voltage is applied to the electrolysis system. In some embodiments, if the stainless steel is chosen as the substrate, during the electrolytic process, the anode side is attracted by the hydroxyl groups according with the applied positive voltage. Simultaneously, the hydroxyl groups are oxidized to form a uniform and complete chromium oxide layer on the surface of the stainless steel substrate. The hydrophilicity of the surface is enhanced, so that the contact angle of the surface of the substrate is reduced. When the applied voltage is 0 to 100 V, the surface of the substrate has a contact angle in the range of between 50° to 65°.

In other embodiments, the substrate is deployed on the cathode side of the electrolysis system, and then a negative voltage is applied to the electrolysis system. In some embodiments, if the stainless steel is chosen as the substrate, during the deionized water dissociation process, the cathode side is attracted by the hydrogen groups according with the applied negative voltage. The chromium oxide on the surface of the substrate stainless steel substrate is attracted by the hydrogen groups. A metal-hydroxyl layer is formed on the substrate, so that the hydrophilicity of the surface is enhanced, and the contact angle of the surface of the substrate is reduced. When the applied voltage is 0 to −100 V, the surface of the substrate has a contact angle of the substrate in the range of between 5° to 30°. It should be noted that the applied voltage is preferred to be in the range of −45 to 100 V to avoid the crystallinity of the piezoactive thin film declining greatly.

An inter-diffusion effect of substances (metal ions or oxygen ions) is produced between the substrate and the piezoactive thin film, so that the electrical properties will be affected. To solve forgoing problem, Step 130 is applied. In this step S130, a buffer layer is deposited on the substrate for preventing thermal diffusion of metal elements or oxygen ions within the substrate. The material of the buffer layer comprises platinum (Pt), titanium (Ti), or oxide electrode.

In step S140, a layer of the piezoactive thin film is forming on the substrate. The layer of the piezoactive thin film is formed on the substrate by spin-coating, sputtering, depositing, roll-to-roll process, inkjet printing, electrophoretic depositing, or dip-coating. In another embodiment, the layer of the piezoactive thin film is formed on the substrate by preparing a precursor solution first.

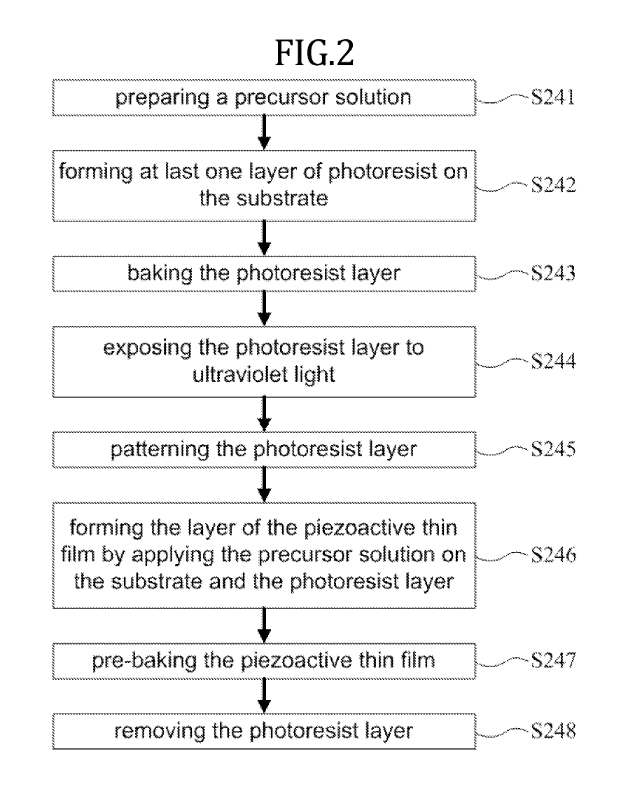

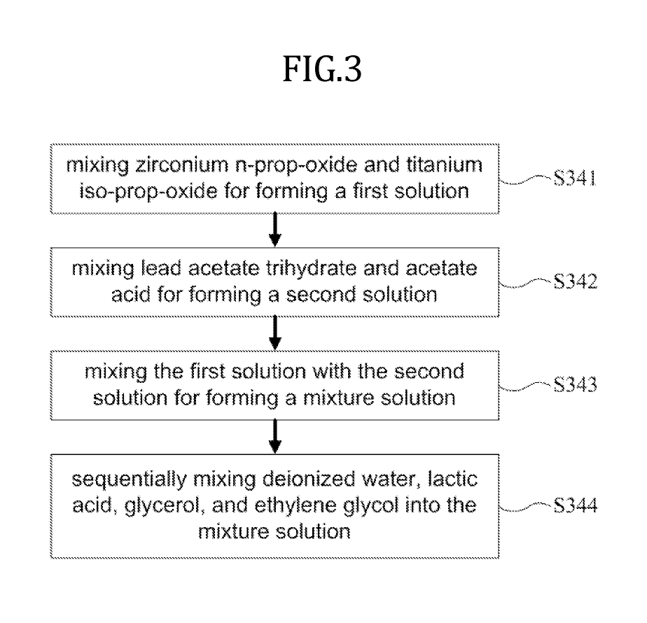

Please referring to FIG. 2 and FIG. 3, FIG. 2 shows a flow chart for forming the piezoactive thin film layer on the substrate and FIG. 3 shows a flow chart for preparing a precursor solution.

In step S241, a precursor solution is prepared. In this preferred embodiment, the precursor solution is prepared in a sol-gel process, which is a simple process. By using the sol-gel process, the fabricated piezoactive thin film is not required to be subject to a higher temperature during annealing.

Among the various piezoelectric-based materials of the piezoactive thin film, lead zirconium titanate (PZT) is a preferred ferroelectric material for transducer applications. The PZT-based transducers have several advantages, such as high sensitivity, wide frequency bandwidth, and fast response. PVDF and P(VDF-TrFE) can also be implemented as ferroelectric materials of the piezoactive thin film. These materials exhibit one or more of the following advantages: mechanical flexibility, biocompatibility, low crystallization temperatures, and a high piezoelectric constant. If the material of the piezoactive thin film is PTZ, the precursor solution may comprise at least zirconium (Zr) ions, titanium (Ti) ions, and lead (Pb) ions. The step S241 of preparing the precursor solution particularly comprises sub-steps S341-S344 described as follows.

In step S341, zirconium n-prop-oxide and titanium iso-prop-oxide are mixed, forming a first solution. In this embodiment, step S341 is performed at room temperature for approximate 30 minutes.

In step S342, the lead acetate trihydrate and acetate acid are mixed, forming a second solution. The temperature of this step is between 90° C. and 130° C., and the time is about 1 to 10 minutes. In this embodiment, the molar ratio of lead acetate: zirconium n-prop-oxide: titanium iso-prop-oxide is 1.1:0.52:0.48. The molar ration of Zr to Ti is X:1-X, wherein 0<X<1, However, it is understood that the preferred molar ratio of Zr:Ti is 0.52:0.48.

In step S343, the first solution is mixed with the second solution, forming a mixture solution.

In step S344, the deionized water, lactic acid, glycerol, and ethylene glycol are sequentially mixed into the mixture solution. To be more specific, the mixture solution is sequentially mixed with DI water for 15 minutes and lactic acid for 15 minutes. Lastly, glycerol and ethylene glycol are mixed sequentially with the mixture solution for 15 minutes. In this embodiment, the concentration of the mixture solution is 1.9M. In addition, by using the sol-gel method, the Zr/Ti composition ratio can be controlled accurately. For this embodiment, a composite material with a high ferroelectric property (Zr:Ti≈52:48) can be produced.

After the precursor solution is prepared, in step S242, at least one layer of photoresist is formed on the substrate. To be more specific, for ensure the uniformity of the photoresist film, the photoresist are applied twice. The photoresist spin-coated on the substrate at 1000 rpm for 10 seconds first, and then the photoresist is spin-coated again at 4000 rpm for 5 minutes.

In step S243, the photoresist layer is baked. The temperature of baking step S243 is in a range from about 70° C. to about 130° C.

In step S244, the photoresist layer is exposed to ultraviolet light. The time of exposing step S244 is in a range from about 10 seconds to about 50 to seconds.

In step S245, the photoresist layer is patterned.

In step S246, the precursor solution is applied on the substrate and the photoresist layer to form the piezoactive thin film. In this embodiment, two steps of applying the precursor solution may be performed. The precursor solution is spin-coated on the substrate and the photoresist layer at 500 rpm for 5 seconds first, and then the precursor solution is spin-coating again at 7000 rpm for 20 seconds.

After forming the piezoactive thin film on the substrate and the photoresist layer, in step S247, the piezoactive thin film is pre-baked. The piezoactive thin film pre-baking temperature is an important factor for the quality of the piezoactive thin film. In this preferred embodiment, the pre-baking temperature is in a range from about 120° C. to about 150° C., and the pre-baking time is in a range from about 3 minutes to about 25 minutes. If the pre-baking temperature is over 200° C. or the pre-baking time is over 25 minutes, it will be difficult to remove the photoresist layer. If the pre-baking time is under 3 minutes, the cracks of the piezoactive thin film will observe.

After the piezoactive thin film is pre-baked, in step S247, the photoresist layer is removed by soaking the substrate into a solvent. In this preferred embodiment, the solvent comprises acetone and isopropyl alcohol (IPA). The substrate is soaked sequentially in the acetone and isopropyl alcohol (IPA), and then the photoresist layer is removed

After the piezoactive thin film is formed, in step S150, the piezoactive thin film is baked. The temperature of baking step S150 is in a range from about 50° C. to about 600° C., and the time is in the range of 1 to 90 minutes. The piezoactive thin film may be baked at least once, to be more specific, in some preferred embodiments, when the PZT is chosen as the material of the piezoactive thin film, more than two baking steps may be implemented. After the layer of the piezoactive thin film (PZT thin film) is applied on the substrate, the baking step S150 may include, e.g., a first baking step at a temperature of between about 100° C. and 200° C. for between about 5 and 15 minutes; and a second baking step at a temperature of between about 450° C. and 550° C. for between about 1 and 10 minutes. In other embodiments, when P(VDF-TrFE) is chosen as the material of the piezoactive thin film, the method of the invention may use a single baking step, which may include baking at a temperature of between about 50° C. and 150° C. for between about 40 and 80 minutes.

After the piezoactive thin film is baked, in step S160, the piezoactive thin film is annealed. When the material of piezoactive thin film is PZT, the temperature for the annealing heat treatment is between about 400° C. and 800° C., and the annealing time is between about 1 and 60 minutes. In this preferred embodiments, the condition for annealing is 650° C. for 10 minutes. In other embodiments, when the material of piezoactive thin film is P(VDF-TrFE), the temperature for the annealing heat treatment is between about 80° C. and 300° C., and the annealing time is between about 1 and 2 hours. The annealing atmosphere may be oxygen, nitrogen, argon, or vacuum, or any combination thereof, at a controlled pressure from vacuum to ambient atmosphere. These atmospheres may also be used for any of the baking and annealing steps, or for all steps.

After the piezoactive thin film is annealed, in step S170, a poling process is performed on the piezoactive thin film. A poling process is applied to the piezoactive thin film to activate the transducer. The poling voltage less than or equal to approximately 5-70 volts.

After poling process is performed on the piezoactive thin film, in step S180, a top electrode is deposited on the piezoactive thin film. The material of the top electrode 130 comprises gold (Au), silver (Ag), aluminum (Al), copper (Cu), platinum (Pt), or another noble metal or metal oxide, and the preferred material is Au and Al. In this step S180, the top electrode is deposited on the piezoactive thin film by using wet etching, dry etching, or a shadow mask process with a metal sputter, to complete the transducer fabrication process. However, in some embodiments, step S180 may also be implemented before step S170. That is, the top electrode is deposited on the piezoactive thin film after the piezoactive thin film is annealed.

After forming the transducer, the transducer is combined with a base element, which may be a plastic element. The edges of the transducer are covered by insulator tapes (such as polyimide tapes) for securing the transducer firmly on the base element.

The present invention has been described with preferred embodiments thereof and it is understood that many changes and modifications to the described embodiments can be carried out without departing from the scope and the spirit of the invention that is intended to be limited only by the appended claims.

What is claimed is:

1. A method of manufacturing a transducer, the method comprising the following steps:
providing a substrate;
performing a surface treatment on the substrate by using an electrolysis system;
forming a layer of a piezoactive thin film on the substrate;
baking the piezoactive thin film; and
annealing the piezoactive thin film.

2. The method of manufacturing the transducer as claimed in claim 1, wherein the step of performing the surface treatment on the substrate comprises deploying the substrate on an anode side of the electrolysis system, and applying a value of positive voltage in a range of between 0 to 100 volts to the electrolysis system, and wherein a surface of the substrate has a contact angle in a range of between 50 degrees to 65 degrees.

3. The method of manufacturing the transducer as claimed in claim 1, wherein the step of performing the surface treatment on the substrate comprises deploying the substrate on a cathode side of the electrolysis system, and applying a value of negative voltage in a range of between −100 to 0 volts to the electrolysis system, and wherein a surface of the substrate has a contact angle in a range of between 5 degrees to 30 degrees.

4. The method of manufacturing the transducer as claimed in claim 1, wherein a solution in the electrolysis system comprises deionized water, hydrohalic acid solution, oxyacid solution, organic acid solution, hydrofluoric acid solution, alkaline metal aqueous solution, alkaline earth metal aqueous solution, or nitrogen compound aqueous solution.

5. The method of manufacturing the transducer as claimed in claim 1, further comprising preparing a precursor solution before forming the layer of the piezoactive thin film on the substrate, wherein the layer of the piezoactive thin film is formed on the substrate by applying the precursor solution on the to substrate.

6. The method of manufacturing the transducer as claimed in claim 5, wherein the precursor solution comprises at least zirconium ions, titanium ions, and lead ions.

7. The method of manufacturing the transducer as claimed in claim 6, wherein a molar ratio of zirconium to titanium is 0.52:0.48.

8. The method of manufacturing the transducer as claimed in claim 6, wherein the step of preparing the precursor solution comprises the following steps:
mixing zirconium n-prop-oxide and titanium iso-prop-oxide for forming a first solution;
mixing lead acetate trihydrate and acetate acid for forming a second solution;
mixing the first solution with the second solution for forming a mixture solution; and
sequentially mixing deionized water, lactic acid, glycerol, and ethylene glycol into the mixture solution.

9. The method of manufacturing the transducer as claimed in claim 5, wherein the step of preparing the precursor solution is performed by a sol-gel process, and the step of forming the layer of the piezoactive thin film on the substrate comprises spin-coating the precursor solution on the substrate.

10. The method of manufacturing the transducer as claimed in claim 9, wherein the to step of forming the layer of the piezoactive thin film on the substrate by spin-coating the precursor solution on the substrate comprises:
forming at last one layer of photoresist on the substrate;
baking the photoresist layer;
exposing the photoresist layer to ultraviolet light;
patterning the photoresist layer;
forming the layer of the piezoactive thin film by applying the precursor solution on the substrate and the photoresist layer;
pre-baking the piezoactive thin film; and
removing the photoresist layer.

11. The method of manufacturing the transducer as claimed in claim 10, wherein the step of pre-baking the piezoactive thin film is in a temperature ranging from 120° C. to 150° C.

12. The method of manufacturing the transducer as claimed in claim 1, wherein the step of forming the layer of the piezoactive thin film on the substrate comprises spin-coating, sputtering or depositing the piezoactive thin film on the substrate.

13. The method of manufacturing the transducer as claimed in claim 1, wherein the substrate comprises metal, stainless steel, glass, indium-tin-oxide coated polyimide, or platinum-coated silicon.

14. The method of manufacturing the transducer as claimed in claim 1, further comprising depositing a buffer layer on the substrate before forming the layer of the piezoactive thin film on the substrate.

15. The method of manufacturing the transducer as claimed in claim 14, wherein a material of the buffer layer comprises platinum, titanium, or oxide electrode.

16. The method of manufacturing the transducer as claimed in claim 1, further comprising performing a poling process on the piezoactive thin film after annealing the piezoactive thin film.

17. The method of manufacturing the transducer as claimed in claim 1, further comprising depositing a top electrode on the piezoactive thin film after annealing the piezoactive thin film.

18. The method of manufacturing the transducer as claimed in claim 17, wherein a material of the top electrode comprises gold or aluminum.
